(19) United States
(12) Patent Application Publication
(10) Pub. No.: US 2021/0054152 A1
(43) Pub. Date: Feb. 25, 2021

(54) HEAT-CURABLE RESIN COMPOSITION, AND ADHESIVE AGENT, FILM, PREPREG, LAMINATE, CIRCUIT BOARD AND PRINTED-WIRING BOARD USING SAME

(71) Applicant: Shin-Etsu Chemical Co., Ltd., Tokyo (JP)

(72) Inventors: Yoshihiro TSUTSUMI, Annaka-shi (JP); Hiroyuki IGUCHI, Annaka-shi (JP); Atsushi TSUURA, Annaka-shi (JP); Naoyuki KUSHIHARA, Annaka-shi (JP); Yuki KUDO, Annaka-shi (JP)

(73) Assignee: Shin-Etsu Chemical Co., Ltd., Tokyo (JP)

(21) Appl. No.: 16/941,202

(22) Filed: Jul. 28, 2020

(30) Foreign Application Priority Data
Aug. 20, 2019 (JP) 2019-150205

(51) Int. Cl. C08G 81/02; C08K 9/06; C09J 187/00; C08J 5/18; C08J 5/24; H05K 1/03

(52) U.S. Cl. CPC C08G 81/025; C08K 9/06; C09J 187/005; C08J 2387/00; C08J 5/24; H05K 1/0373; C08J 5/18

(57) ABSTRACT

Provided are a heat-curable resin composition capable of being turned into a cured product having a high glass-transition temperature, a low dielectric tangent and a superior adhesion to a metal foil; and an adhesive agent, film, prepreg, laminate, circuit board as well as printed-wiring board using such heat-curable resin composition. The heat-curable resin composition contains:
(A) a polyphenylene ether resin having reactive double bonds at molecular chain ends;
(B) a (meth)acrylic acid ester compound;
(C) a cyclic imide compound containing, in one molecule, at least one dimer acid backbone, at least one linear alkylene group having not less than 6 carbon atoms, and at least two cyclic imide groups; and
(D) a reaction initiator.

### BACKGROUND OF THE INVENTION

### Field of the Invention

The present invention relates to a heat-curable resin composition; and an adhesive agent, film, prepreg, laminate, circuit board as well as printed-wiring board using the same.

### Background Art

In recent years, as electronic devices are becoming smaller and more efficient, it is now required that wirings on multi-layer printed wiring boards be formed in a finer and more densified manner. Further, in the next generation, since materials aimed at high-frequency bands are needed, and transmission loss reduction is essential as a countermeasure against noises, it is required that an insulation material superior in dielectric property be used in an insulation layer(s) of a multi-layer printed wiring board.

As an insulation material for use in a multi-layer printed wiring board, there are known, as disclosed in JP-A-2007-254709 and JP-A-2007-254710, an epoxy resin composition(s) containing, for example, an epoxy resin, a particular phenolic curing agent, a phenoxy resin, rubber particles and a polyvinyl acetal resin. However, these materials are not satisfactory in terms of high-frequency use in the fifth-generation (5G) mobile communication system.

In this regard, JP-A-2011-132507 discloses that an epoxy resin composition containing an epoxy resin, an active ester compound and a triazine-containing cresol novolac resin is effective in lowering dielectric tangent. However, even this material is not satisfactory for high-frequency use, and an even lower dielectric tangent is required.

Meanwhile, WO 2016-114287 discloses a resin composition containing a long-chain alkyl group-containing bismaleimide resin as a non-epoxy material and a curing agent. WO 2016-114287 also discloses that a resin film comprised of this resin composition is superior in low dielectric property. However, since this resin composition is technically a combination of the long-chain alkyl group-containing bismaleimide resin and a hard low-molecular aromatic maleimide, there are problems with compatibility. Further, a cured product of this resin composition has variations in properties and curing unevenness, and does not have a high glass-transition temperature (Tg) of 150° C. or higher as required for substrate application. A composition disclosed in JP-A-2017-002124 uses a non-reactive polyphenylene ether, and thus has a handling property and adhesion that are inferior to those of heat-curable resins. In addition, a composition disclosed in WO 2016-117554 contains a thermoplastic elastomer; the composition is intended for use in a soft adhesive agent, and is not preferable for substrate material application.

### SUMMARY OF THE INVENTION

Thus, it is an object of the present invention to provide a heat-curable resin composition capable of being turned into a cured product having a high glass-transition temperature, a low dielectric tangent and a superior adhesion to a metal foil; and an adhesive agent, film, prepreg, laminate, circuit board as well as printed-wiring board using such heat-curable resin composition.

The inventors of the present invention diligently conducted a series of studies to solve the above problems, and completed the invention as follows. That is, the inventors found that the following heat-curable resin composition could achieve the above objectives.

[1]

A heat-curable resin composition comprising:
(A) a polyphenylene ether resin having reactive double bonds at molecular chain ends;
(B) a (meth)acrylic acid ester compound;
(C) a cyclic imide compound containing, in one molecule, at least one dimer acid backbone, at least one linear alkylene group having not less than 6 carbon atoms, and at least two cyclic imide groups; and
(D) a reaction initiator.
   [2]

The heat-curable resin composition according to [1], wherein the polyphenylene ether resin as the component (A) is represented by the following formula (1):

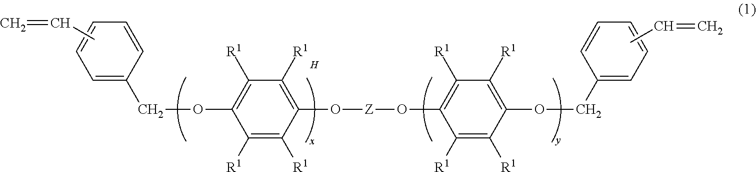

wherein R¹ independently represents a hydrogen atom or an aliphatic hydrocarbon group having 1 to 6 carbon atoms; Z represents a divalent aromatic hydrocarbon group having 6 to 24 carbon atoms; x represents a number of 0 to 20, y represents a number of 0 to 20, provided that x and y do not both represent 0 at the same time.
[3]

The heat-curable resin composition according to [2], wherein the divalent aromatic hydrocarbon group having 6 to 24 carbon atoms, as represented by Z in the formula (1), is selected from divalent aromatic hydrocarbon groups expressed by the following formula (2):

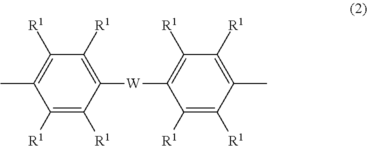

wherein R¹ independently represents a hydrogen atom or an aliphatic hydrocarbon group having 1 to 6 carbon atoms; W represents a single bond, or a linear, branched or cyclic divalent aliphatic hydrocarbon group having 1 to 10 carbon atoms.
[4]

The heat-curable resin composition according to any one of [1] to [3], wherein the polyphenylene ether resin as the component (A) is represented by the following formula (3):

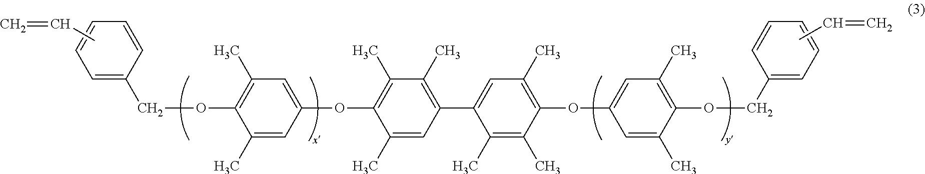

wherein x′ represents 0 to 20, y′ represents 0 to 20, provided that x′ and y′ do not both represent 0 at the same time.
[5]

The heat-curable resin composition according to any one of [1] to [4], wherein the (meth)acrylic acid ester compound as the component (B) has not less than 8 carbon atoms, and at least 2 (meth)acrylic groups in one molecule.

[6]

The heat-curable resin composition according to any one of [1] to [5], wherein the cyclic imide compound as the component (C) is represented by the following formula (4):

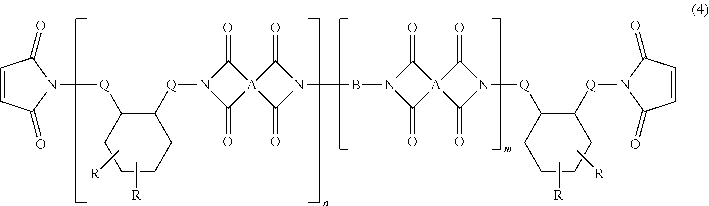

wherein A independently represents a tetravalent organic group having an aromatic or aliphatic ring; B represents an alkylene group having 6 to 18 carbon atoms and a divalent aliphatic ring that may contain a hetero atom; Q independently represents a linear alkylene group having not less than 6 carbon atoms; R independently represents a linear or branched alkyl group having not less than 6 carbon atoms; n represents a number of 1 to 10; m represents a number of 0 to 10.
[7]

The heat-curable resin composition according to [6], wherein A in the formula (4) represents any of the following structures:

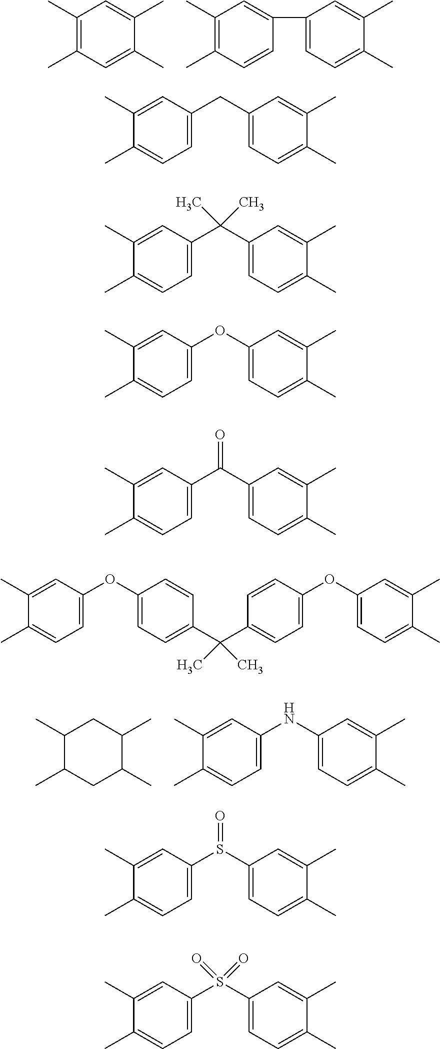

wherein bonds in the above structural formulae that are yet unbonded to substituent groups are to be bonded to carbonyl carbons forming cyclic imide structures in the general formula (4).
[8]

The heat-curable resin composition according to any one of [1] to [7], wherein not lower than 5% by mass of the cyclic imide compound as the component (C) has a number average molecular weight of 1,000 or smaller.

[9]

The heat-curable resin composition according to any one of [1] to [8], further comprising an inorganic filler as a component (E).

[10]

The heat-curable resin composition according to [9], wherein the inorganic filler as the component (E) has been treated with a silane coupling agent having organic groups capable of reacting with the component (C).

[11]

An adhesive agent comprising the heat-curable resin composition according to any one of [1] to [10].

[12]

A film comprising the heat-curable resin composition according to any one of [1] to [10].

[13]

A cured product of the heat-curable resin composition according to any one of [1] to [10].

[14]

A prepreg having the cured product according to [13].

[15]

A laminate having the cured product according to [13].

[16]

A circuit board having the cured product according to [13].

[17]

A printed-wiring board having the cured product according to [13].

The heat-curable resin composition of the present invention is capable of being turned into a cured product having a high glass-transition temperature, a low dielectric tangent, and a superior adhesion to a metal foil. Thus, this heat-curable resin composition is suitable for use in an adhesive agent, a film, a prepreg, a laminate, a circuit board and a printed-wiring board.

### DETAILED DESCRIPTION OF THE INVENTION

The present invention is described in detail hereunder.

### (A) Polyphenylene Ether Resin Having Reactive Double Bonds at Molecular Chain Ends

A component (A) is a polyphenylene ether resin having reactive double bonds at molecular chain ends. The component (A) is a resin serving as a base of the resin composition of the present invention, and is used to improve a heat resistance, dielectric property and rigidity of a cured product of the composition of the invention.

A preferable example of the component (A) is represented by the following formula (1):

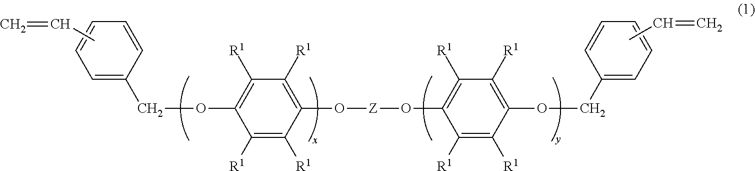

In the formula (1), R¹ independently represents a hydrogen atom or an aliphatic hydrocarbon group having 1 to 6 carbon atoms; Z represents a divalent aromatic hydrocarbon group having 6 to 24 carbon atoms; x represents a number of 0 to 20, y represents a number of 0 to 20, provided that x and y do not both represent 0 at the same time.

While R¹ in the formula (1) independently represents a hydrogen atom or an aliphatic hydrocarbon group having 1 to 6 carbon atoms, a hydrogen atom and an alkyl group are preferred in terms of raw material availability. Examples of such alkyl group include a methyl group, an ethyl group, a propyl group, an isopropyl group, an n-butyl group, an isobutyl group, a pentyl group and a hexyl group. Among these alkyl groups, a methyl group is particularly preferred.

Z in the formula (1) represents a divalent aromatic hydrocarbon group having 6 to 24 carbon atoms. It is preferred that Z represent a divalent aromatic hydrocarbon group expressed by the following formula (2):

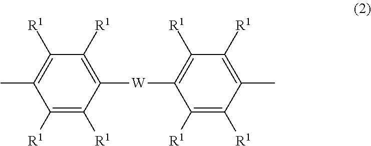

In the formula (2), R¹ independently represents a hydrogen atom or an aliphatic hydrocarbon group having 1 to 6 carbon atoms; W represents a single bond, or a linear, branched or cyclic divalent aliphatic hydrocarbon group having 1 to 10 carbon atoms.

W in the formula (2) represents a single bond, or a linear, branched or cyclic divalent aliphatic hydrocarbon group having 1 to 10 carbon atoms. In terms of raw material availability and heat resistance, preferred are a single bond, a linear divalent aliphatic hydrocarbon group having 1 to 3 carbon atoms, or a branched divalent aliphatic hydrocarbon group having 3 to 5 carbon atoms.

Specific examples of the divalent aromatic hydrocarbon group represented by the formula (2) include those having the following structures.

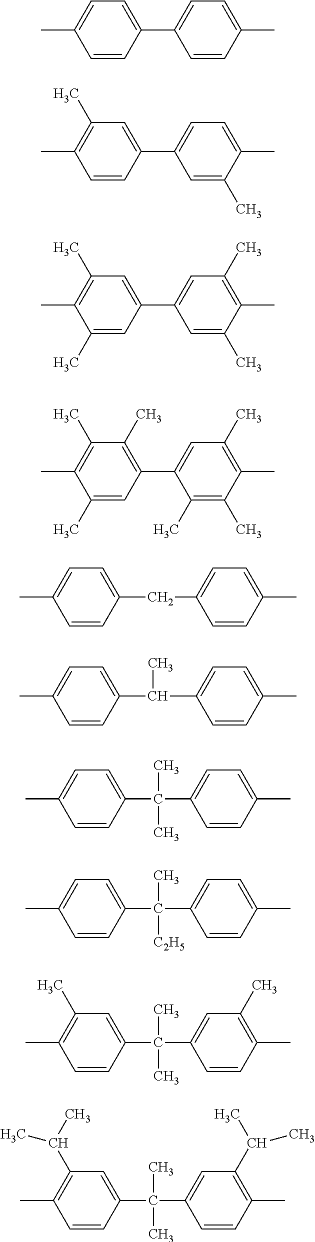

A particularly preferable example of the component (A) may be that represented by the following formula (3).

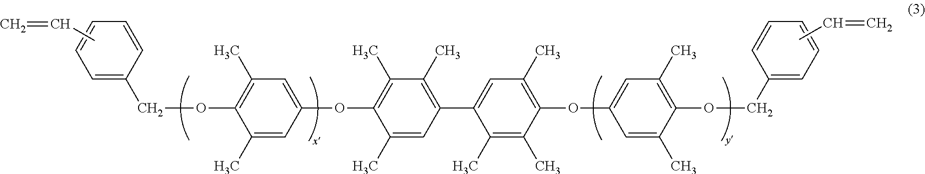

In the formula (3), x′ represents 0 to 20, y′ represents 0 to 20, provided that x′ and y′ do not both represent 0 at the same time.

In view of a handling property such as non-stickiness and a compatibility with an organic solvent(s) as well as other components, the number average molecular weight (Mn) of the polyphenylene ether resin as the component (A), when measured by gel permeation chromatography (GPC), is preferably 500 to 5,000, particularly preferably 800 to 3,000, in terms of polystyrene.

The number average molecular weight (Mn) referred to in the present invention is a number average molecular weight measured by GPC under the following conditions, using polystyrene as a reference substance.

### [Measurement Condition]

Developing solvent: tetrahydrofuran
Flow rate: 0.35 mL/min

### Detector: RI

Column: TSK-GEL H type (by TOSOH CORPORATION)
Column temperature: 40° C.
Sample injection volume: 5 μL

One kind of the polyphenylene ether resin as the component (A) may be used alone, or two or more kinds thereof may be used in combination.

It is preferred that the component (A) be contained in the composition of the present invention by an amount of 10 to 70% by mass, more preferably 12 to 60% by mass, and even more preferably 15 to 50% by mass.

### (B) (Meth)Acrylic Acid Ester Compound

A component (B) is a (meth)acrylic acid ester compound, and is a compound for imparting a flexibility to an uncured resin composition, and improving an adhesion force of a metal foil or the like to a base material. While there are no particular restrictions on a (meth)acrylic acid ester compound used, it is preferred that the compound have, in one molecule, at least 2 (meth)acrylic groups, more preferably 2 to 4 (meth)acrylic groups, in terms of curability and rigidity of the cured product. Further, a (meth)acrylic acid ester compound having not less than 8 carbon atoms is preferred, and a (meth)acrylic acid ester compound having 12 to 30 carbon atoms is more preferred. When the number of carbon atoms is not smaller than 8, there will be achieved an effect of improving an adhesion force of the resin composition, and the flexibility of an uncured resin composition will be improved as well.

As the (meth)acrylic acid ester compound, preferred are those that are in a liquid state at room temperature (25° C.), and more preferred are those having no aromatic backbone. Specific examples of the (meth)acrylic acid ester compound include 1,6-hexanediol diacrylate, neopentyl glycol diacrylate, dipropylene glycol diacrylate, tricyclodecane dimethanol diacrylate, 9,9-bis[4-(2-hydroxyethoxy)phenyl]fluorene diacrylate, bisphenol A-type diacrylate, trimethylolpropane triacrylate, tris(2-acryloxyethyl)isocyanurate, ditrimethylolpropane tetraacrylate, 1,6-hexanediol dimethacrylate, neopentyl glycol methacrylate, dipropylene glycol dimethacrylate, tricyclodecane dimethanol dimethacrylate, 9,9-bis[4-(2-hydroxyethoxy)phenyl]fluorene dimethacrylate, bisphenol A-type dimethacrylate, trimethylolpropane trimethacrylate, tris(2-methacryloxyethyl)isocyanurate and ditrimethylolpropane tetramethacrylate. Among these compounds, particularly preferred are tricyclodecane dimethanol diacrylate and tricyclodecane dimethanol dimethacrylate.

(C) Cyclic Imide Compound Containing, in One Molecule, at Least One Dimer Acid Backbone, at Least One Linear Alkylene Group Having not Less than 6 Carbon Atoms, and at Least Two Cyclic Imide Groups

The component (C) is a cyclic imide compound, and contains, in one molecule, at least one dimer acid backbone, at least one linear alkylene group having not less than 6 carbon atoms, and at least two cyclic imide groups. When such cyclic imide compound contains a linear alkylene group(s) having not less than 6 carbon atoms, not only the cured product of a composition containing the cyclic imide compound will exhibit a superior dielectric property, but a tracking resistance will also be improved due to a lower content ratio of phenyl groups. Further, when such cyclic imide compound has a linear alkylene group(s), the cured or uncured product of a composition containing the cyclic imide compound will be able to exhibit a lower elasticity such that a flexibility will then be imparted to the resin composition and the cured product of this composition. In general, a flexibility imparting agent for a resin composition has a problem of being inferior in heat resistance. The component (C) is thus effective in solving such problem as it has a cyclic imide backbone superior in heat resistance.

A preferable example of the cyclic imide compound as the component (C) may be a maleimide compound, and a maleimide compound represented by the following formula (4) is more preferred.

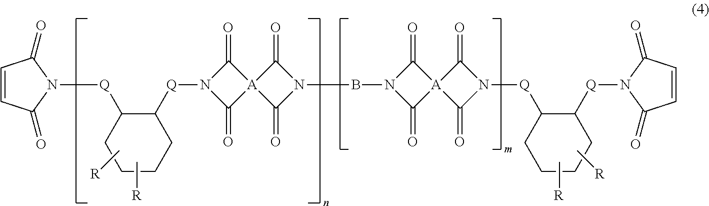

In the formula (4), A independently represents a tetravalent organic group having an aromatic or aliphatic ring; B represents an alkylene group having 6 to 18 carbon atoms and a divalent aliphatic ring that may contain a hetero atom. Q independently represents a linear alkylene group having not less than 6 carbon atoms. R independently represents a linear or branched alkyl group having not less than 6 carbon atoms. n represents a number of 1 to 10. m represents a number of 0 to 10.

Q in the formula (4) represents a linear alkylene group, each having not less than 6 carbon atoms, preferably 6 to 20 carbon atoms, and more preferably 7 to 15 carbon atoms.

Further, R in the formula (4) represents an alkyl group, and may be either a linear or branched alkyl group. Each alkyl group represented by R has not less than 6 carbon atoms, preferably 6 to 12 carbon atoms.

A in the formula (4) represents a tetravalent organic group having an aromatic or aliphatic ring. Particularly, it is preferred that A represent any one of the tetravalent organic groups expressed by the following structural formulae.

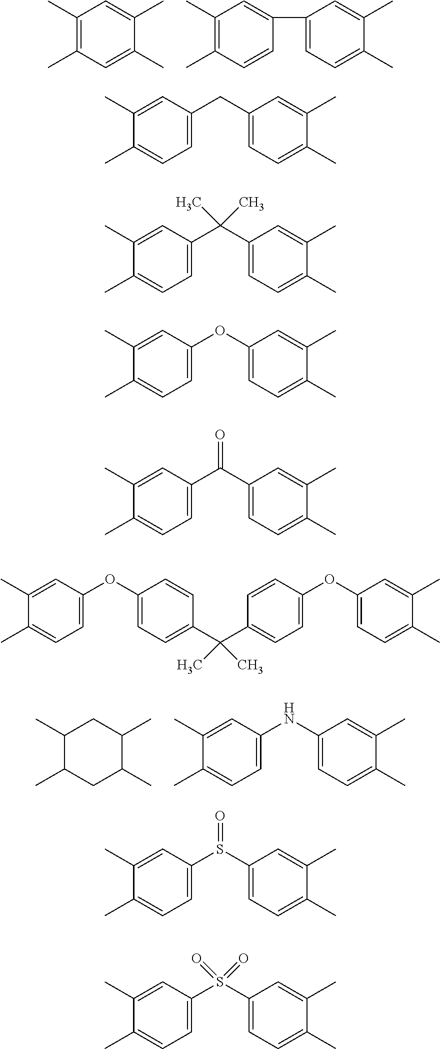

wherein bonds in the above structural formulae that are yet unbonded to substituent groups are to be bonded to carbonyl carbons forming cyclic imide structures in the formula (4).

Further, B in the formula (4) represents an alkylene group having 6 to 18 carbon atoms and a divalent aliphatic ring that may contain a hetero atom. This alkylene group preferably has 8 to 15 carbon atoms. It is preferred that B in the formula (4) represent any one of the alkylene groups expressed by the following structural formulae.

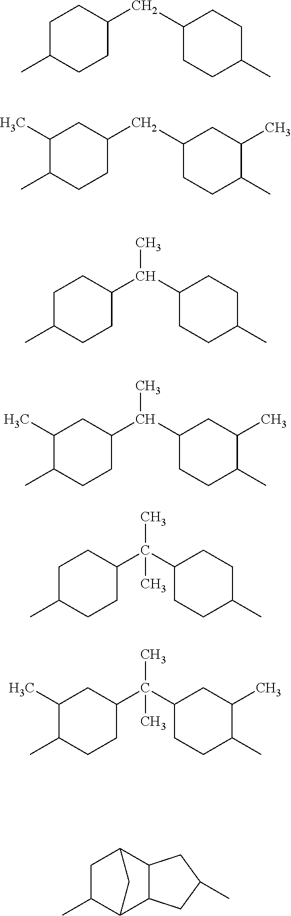

Bonds in the above structural formulae that are yet unbonded to substituent groups are to be bonded to nitrogen atoms forming cyclic imide structures in the formula (4).

n in the formula (4) represents a number of 1 to 10, preferably a number of 2 to 7. m in the formula (4) represents a number of 0 to 10, preferably a number of 0 to 7.

There are no particular restrictions on the number average molecular weight (Mw) of the cyclic imide compound as the component (C), as there are no particular restrictions on the properties thereof at room temperature. However, it is more preferred that the number average molecular weight of the cyclic imide compound be 500 to 50,000, particularly preferably 800 to 40,000, in terms of polystyrene when measured by gel permeation chromatography (GPC). When such molecular weight is not smaller than 500, an obtained composition containing the cyclic imide compound can be easily turned into a film. When such molecular weight is not larger than 50,000, there exists no concern that a fluidity may be impaired due to an excessively high viscosity of the composition obtained, which then results in a favorable moldability when performing laminate molding or the like.

As the cyclic imide compound as the component (C), there may be used commercially available products such as BMI-689, BMI-1500, BMI-2500, BMI-3000 and BMI-5000 (all by Designer Molecules Inc.). Here, one kind of cyclic imide compound may be used alone, or two or more kinds thereof may be used in combination.

In the composition of the present invention, it is preferred that the component (A) be contained in an amount of 30 to 70% by mass, the component (B) be contained in an amount of 3 to 20% by mass, and the component (C) be contained in an amount of 20 to 70% by mass, more preferably 30 to 60% by mass, per a sum total of the heat-curable resin components which are the components (A), (B) and (C). When the amounts of the components (A), (B) and (C) are within these ranges, there will be obtained a composition having well-balanced properties.

### (D) Reaction Initiator

A reaction initiator as a component (D) is added to promote a cross-linking reaction of the heat-curable resin components which are the components (A), (B) and (C). There are no particular restrictions on the component (D) so long as it is capable of promoting the cross-linking reaction. Examples of the component (D) include ion catalysts such as imidazoles, tertiary amines, quaternary ammonium salts, borontrifluoride-amine complexes, organo-phosphines and organo-phosphonium salts; and radical polymerization initiators such as organic peroxides, hydroperoxide and azo-iso-butyronitrile. Among these reaction initiators, imidazoles and organic peroxides are preferred. Examples of the imidazoles include 2-methylimidazole, 2-ethyl-4-methylimidazole, 2-phenylimidazole, 1-benzyl-2-phenylimidazole and 2-phenyl-4,5-dihydroxymethylimidazole. Examples of the organic peroxides include dicumylperoxide, t-butylperoxy benzoate, t-amylperoxy benzoate, dibenzoyl peroxide and dilauroyl peroxide. One kind of such reaction initiator as the component (D) may be used alone, or two or more kinds thereof may be used in combination.

It is preferred that the reaction initiator(s) be added in an amount of 0.05 to 10 parts by mass, more preferably 0.1 to 5 parts by mass, per 100 parts by mass of the sum total of the heat-curable resin components which are the components (A), (B) and (C). When the amount of the reaction initiator is outside the above ranges, the cured product of the resin composition of the present invention may exhibit an unfavorable balance between heat resistance and moisture resistance, and/or an extremely slow or fast curing speed may be observed at the time of performing molding.

A 60% by mass anisole solution of a mixture of the components (A), (B), (C) and (D) is transparent at 25° C. The fact that this anisole solution is transparent clearly indicates that all the components are uniformly dispersed therein, which makes it less likely to cause unevenness in the cured product at the time of curing, and thus improves a property uniformity of the product.

In the present invention, the term “transparent” refers to a state where even when the solution is colored, no insoluble residues and no turbidity are visible, and where the anisole solution of the mixture, when contained in a quartz cell, exhibits a direct light transmittance of not lower than 50% at a light path of 1 mm and a wavelength of 740 nm.

Other than the above components, the following optional components may be further added to the composition of the present invention.

### (E) Inorganic Filler

An inorganic filler as a component (E) may be added to improve a strength and/or rigidity of the cured product of the heat-curable resin composition of the invention, and adjust a thermal expansion coefficient of such cured product. As such inorganic filler as the component (E), there may be employed those that are usually added to epoxy resin compositions and silicone resin compositions. Examples of such inorganic filler include silicas such as a spherical silica, a molten silica and a crystalline silica; alumina; silicon nitride; aluminum nitride; boron nitride; barium sulfate; talc; clay; aluminum hydroxide; magnesium hydroxide; calcium carbonate; glass fibers; and glass particles. Further, in order to improve a dielectric property, there may also be used a fluorine-containing resin, a coating filler and/or hollow particles.

One kind of the inorganic filler as the component (E) may be used alone, or two or more kinds thereof may be used in combination.

While there are no particular restrictions on the average particle size and shape of the inorganic filler as the component (E), a spherical silica having an average particle size of 0.5 to 5 μm is particularly preferable if molding the composition into the shape of a film. Here, an average particle size refers to a value obtained as a mass average value D₅₀ (or median diameter) in a particle size distribution measurement by a laser diffraction method.

Further, it is preferred that the inorganic filler as the component (E) be surface-treated with a silane coupling agent having organic groups capable of reacting with the cyclic imide groups in the component (C). Examples of such coupling agent include an epoxy group-containing alkoxysilane, an amino group-containing alkoxysilane, a (meth)acrylic group-containing alkoxysilane and unsaturated alkyl group-containing alkoxysilane.

As the abovementioned coupling agent, a (meth)acrylic group- and/or amino group-containing alkoxysilanes are preferred in terms of lowering a viscosity and thixotropy of the uncured resin composition, improving mechanical properties and a dielectric property of the cured product, and even improving an adhesion to a metal such as copper. Specific examples of the silane coupling agent include 3-methacryloxypropyltrimethoxysilane, 3-acryloxypropyltrimethoxysilane, N-phenyl-3-aminopropyltrimethoxysilane, N-2-(aminoethyl)-3-aminopropyltrimethoxysilane and 3-aminopropyltrimethoxysilane.

Any one of these coupling agents may be used alone, or two or more of them may be used in combination.

The inorganic filler(s) as the component (E) is added in an amount of 50 to 800 parts by mass, particularly preferably 100 to 700 parts by mass, per 100 parts by mass of the sum total of the heat-curable resin components which are the components (A), (B) and (C). When the amount of the inorganic filler as the component (E) added is not smaller than 100 parts by mass, but smaller than 700 parts by mass, a sufficient strength can be achieved due to a low coefficient of thermal expansion (CTE) of the cured product, a flexibility required for a film will thus not be lost, and appearance defects will not occur accordingly. Here, it is preferred that such inorganic filler be contained in an amount of 10 to 90% by mass, particularly preferably 15 to 85% by mass, with respect to the whole composition.

### (F) Silane Coupling Agent

A silane coupling agent that has been used as the surface treatment agent for treating the inorganic filler as the component (E) may also be added as a component (F) to the composition of the present invention. This component (F) is added to improve an adhesion and dielectric property of the heat-curable resin composition of the present invention. While there are no particular restrictions on the kind of the silane coupling agent as the component (F), a (meth)acrylic group-containing alkoxysilane is particularly preferred in terms of improving an adhesion force.

It is preferred that the component (F) be contained in an amount of 0.1 to 8.0% by mass, particularly preferably 0.3 to 6.0% by mass, per the sum total of the heat-curable resin components which are the components (A), (B) and (C). When such amount of the component (F) is lower than 0.1% by mass, there cannot be achieved an adhesion effect to a base material; and an effect of improving dielectric property. Further, when the amount of the component (F) is greater than 8.0% by mass, voids and pinholes may occur easily when removing a solvent, and bleed out may occur from resin surface, after turning the composition into a varnish, for example.

### Other Additives

Various additives may be further added to the heat-curable resin composition of the present invention if necessary. As long as the effects of the invention will not be impaired, these additives may include, for example, an epoxy resin for improving resin properties; an organopolysiloxane having a reactive functional group(s) such as an amino group and an epoxy group; a silicone oil having no functional groups, such as dimethylsilicone oil; other heat-curable resins such as cyanate resin; a thermoplastic resin; a thermoplastic elastomer; an organic synthetic rubber; a light stabilizer; a pigment; a dye; a coupling agent other than a silane coupling agent, such as an organic titanium compound for improving a wettability to a filler and an adhesion to a base material; an ion trapping agent for improving electric properties; and a phosphorus compound as well as a non-halogen flame retardant such as a metal hydrate for imparting a flame retardancy. Further, a fluorine-containing material or the like may be added to improve dielectric property.

### Method for Producing Resin Composition Solution (Varnish)

The resin composition of the present invention may be dissolved in an organic solvent to obtain a varnish (resin composition solution), and this varnish may then be applied to a base material to form a film. A method for producing the resin composition solution is described hereunder. The resin composition solution can be obtained by dissolving, in an organic solvent, components such as the components (A), (B), (C) and (D) as the raw materials of the present invention; heating may also be performed while dissolving these components. Each component may be separately dissolved in an organic solvent at first, followed by combining given amounts of the solutions obtained; or a mixture of the components may be prepared in advance, followed adding thereto a given amount of an organic solvent so as to dissolve the components. As a method for dissolution, there may be employed, for example, a method of combining the components and an organic solvent in a stirrer-equipped container, and then performing stirring.

There are no particular restrictions on an organic solvent used, as long as each component is soluble therein. Preferable examples of such organic solvent include toluene, xylene, anisole, cyclohexanone and cyclopentanone. Any one of these organic solvents may be used alone, or a mixture of two or more of them may be used.

The concentration of the resin composition of the present invention in the resin composition solution (varnish) is preferably 5 to 80% by mass, more preferably 10 to 75% by mass.

### Adhesive Agent/Film/Laminate

The resin composition of the present invention can be used as an adhesive agent. There, although the resin composition may be applied, dried and cured, it may also be turned into the shape of a film so as to be used as an adhesive film (bonding film). For example, when producing a base material-attached adhesive film by laminating the aforementioned adhesive film on a base material, the varnish of the resin composition of the present invention may be applied to the base material and then dried, or the adhesive film may at first be produced on a mold release film or a mold release paper, followed by attaching them to the base material.

Examples of the base material include various plastic films, mold lease papers and metal foils. Examples of such plastic films include a polyolefin film such as that made of polyethylene, polypropylene or polyvinyl chloride; a polyester film such as that made of polyethylene terephthalate (PET) or polyethylene naphthalate; a polycarbonate film; and a polyimide film. Examples of the metal foils include a copper foil and an aluminum foil. Here, a product with the film being laminated on a metal foil is referred to as a metal-attached laminate. The base material and a later-described protective film (separator) may already be subjected to a surface treatment such as a matte treatment and a corona treatment in advance. Further, the base material and the later-described protective film (separator) may already be subjected to a mold release treatment in advance, using a mold release agent such as a silicone resin-based mold release agent, an alkyd resin-based mold release agent and a fluorine resin-based mold release agent.

Moreover, as another method for producing the adhesive film, there is also a production method using an extruder equipped with a T-die. In this production method, instead of a varnish, there is used a heat-curable resin composition prepared by melting and mixing the components.

As a method for applying the varnish of the resin composition, a normal coating or printing method may be used. Specific examples of such method include coating methods such as air doctor coating, bar coating, blade coating, knife coating, reverse coating, transfer roll coating, gravure roll coating, kiss coating, cast coating, spray coating, slot orifice coating, calender coating, dam coating, dip coating and die coating; and printing methods such as intaglio printing e.g. gravure printing, and stencil printing e.g. screen printing.

While there are no particular restrictions on a drying condition for drying the organic solvent, it is preferred that a drying temperature be 60 to 150° C.; the drying temperature can be adjusted appropriately based on the organic solvent and a reaction promoter. When the drying temperature is lower than 60° C., the solvent is more likely to remain in the adhesive agent or film, and the resin components applied may undergo phase separation or even be precipitated as the solvent volatilizes. When the drying temperature is higher than 150° C., the resin composition may harden, and a coating film may turn rough due to a rapid temperature rise. There are also no particular restrictions on a drying time. However, a drying time of 1 to 30 min is preferred in terms of practicality. Further, while the thickness of the film can be adjusted based on the concentration of the varnish and a coating thickness, it is preferred that the thickness of a resin composition layer in the adhesive film be 10 to 120 μm. Especially, if using the adhesive film in a later-described circuit board, it is preferred that the thickness of the resin composition layer in the adhesive film be as large as or larger than the thickness of a conductor layer of the circuit board. Since a conductor layer of a circuit board usually has a thickness of 5 to 70 μm, it is preferred that the resin composition layer have a thickness of 10 to 100 μm, more preferably 15 to 80 μm in terms of forming a thinner layer(s).

A mold release film or mold release paper as a protective film may then be laminated on the adhesive film that has been dried. As such mold release film or mold release paper, there may be listed, for example, a polypropylene-coated paper; a silicone mold release paper; and a material prepared by applying a mold release agent to any of the abovementioned plastic films that are usable as base materials. When there is employed a mold release film using a plastic film as its parent material, the separator preferably has a thickness of 10 to 100 μm; when there is employed a mold release paper using paper as its parent material, the separator preferably has a thickness of 50 to 200 μm. By laminating the protective film, dust or the like can be prevented from adhering to the surface of the resin composition layer, and scars can be prevented from occurring thereon. The adhesive film can be stored in a rolled state.

### Prepreg

A prepreg contains the heat-curable resin composition of the present invention, and can be produced as follows. That is, a reinforcement base material is to be impregnated or coated with the heat-curable resin composition of the invention, followed by performing heating so as to dry and semi-cure the heat-curable resin composition.

As the reinforcement base material, there may be used those that are generally used as base materials for prepregs, such as a glass cloth, a quartz glass, an aramid unwoven cloth and a liquid crystal polymer unwoven cloth. Particularly, a quartz glass cloth is preferable for a high-frequency use requiring a low dielectric property.

As a method for performing impregnation or coating, there may be employed a hot melt method or a solvent method.

A hot melt method is a method where a die coater is, for example, used to directly apply the heat-curable resin composition of the present invention in a molten state to a reinforcement base material to produce a film-shaped laminating material, and thus laminate such film-shaped laminating material on the reinforcement base material.

A solvent method is a method where a reinforcement base material is to be dipped into the varnish prepared by the abovementioned method, followed by drying the same.

Further, the prepreg may also be produced by continuously heat-laminating the adhesive film prepared by the above method from both surfaces of the reinforcement base material under a heated and pressurized condition. As a support or protective film, there may be used those listed in the description of the adhesive film.

By heating the reinforcement base material impregnated or coated with the heat-curable resin composition of the present invention at 60 to 150° C. for 5 to 60 min, the heat-curable resin composition will be in a dry and semi-cured state.

In the prepreg of the present invention, it is preferred that the heat-curable resin composition of the invention be contained in an amount of 25 to 75% by mass with respect to the reinforcement base material.

### Circuit Board/(Multi-Layer) Printed-Wiring Board

A circuit board of the present invention has an insulation layer which is the cured product of the heat-curable resin composition of the invention. Examples of a substrate used in the circuit board of the invention include a glass epoxy substrate, a metal substate, a polyester substrate, a polyimide substrate, a BT resin substrate and a heat-curable polyphenylene ether substrate. Here, a circuit board refers to that having a patterned conductor layer (circuit) formed on one or both surfaces of the above type of substrate, and also includes a (multi-layer) printed-wiring board with conductor layers and insulation layers being alternately laminated on top of one another, and with a patterned conductor layer (circuit) being formed on one or both surfaces of the outermost layer(s). Particularly, the surface of the conductor layer may already be subjected to a blackening treatment and a roughening treatment such as copper etching in advance.

As a method for forming an insulation layer on the circuit board, there may be employed a method where the varnish prepared by the above method is to be applied to the circuit board before being dried and cured by heat. Specifically, a dispenser is used to perform the application, and drying is then performed at 60 to 150° C. for 0.5 to 2 hours.

Further, as another method for forming the insulation layer(s) on a circuit board, there may be employed a method where the film-shaped laminating material prepared by the above method is to be laminated on one or both surfaces of the circuit board, using a vacuum laminator. When the film-shaped laminating material has the protective film, the protective film is to be removed at first, followed by preheating the film-shaped laminating material and the circuit board if necessary, and then laminating the film-shaped laminating material on the circuit board under a pressurized and heated condition. After the lamination is completed, it is preferred that a smoothing treatment be performed on the laminated film-shaped laminating material by, for example, hot-pressing such film-shaped laminating material under a normal pressure. Conditions similar to those of the above heating and pressurization conditions for lamination may be employed as the conditions for the smoothing treatment. The smoothing treatment can be performed using a commercially available laminator. Here, the lamination treatment and the smoothing treatment may also be performed in a continuous manner, using the abovementioned commercially available vacuum laminator.

The insulation layer can be formed in a way such that after the film-shaped laminating material has been laminated on the circuit board and then cooled to near room temperature, the support may then be peeled off if it needs to be peeled off, followed by heating and thus curing the resin composition. Here, for example, an order in which the support is to be peeled off may be appropriately shuffled. In this way, the insulation layer can be formed on the circuit board.

Further, as another method for forming the insulation layer(s) on a circuit board, there may also be employed a method where the film-shaped laminating material prepared by the above method is to be laminated on one or both surfaces of the circuit board, using a vacuum press machine. In this method, heating and pressurization are performed under a reduced pressure, using a general vacuum hot press machine, thereby allowing the resin composition on the circuit board to be heated and cured so as to form an insulation layer(s).

Further, there may also be employed a method for producing a circuit board ((multi-layer) printed-wiring board), using the prepreg prepared by the above method. That is, the circuit board may be produced as follows. One or more pieces of the prepreg of the present invention may at first be laid on an interior circuit board, followed by performing press lamination under a pressurized and heated condition with a metal plate being sandwiched via a mold release film.

After the circuit board has been produced, via holes and through holes may then be formed by boring the insulation layer formed on the circuit board, the surface of the insulation layer may be subjected to a roughening treatment, and a conductor layer may be formed by plating the insulation layer. These processes may be carried out in accordance with methods for producing a general circuit board or a (multi-layer) printed-wiring board.

Therefore, the heat-curable resin composition of the present invention is suitable for use in a printed-wiring board, particularly in those of a rigid type.

A heating and curing conditions for these compositions may be appropriately selected based on, for example, the kinds and amounts of the resin components contained in the resin composition. It is preferred that such conditions be selected from a range of 150 to 220° C. for 20 to 300 min, more preferably from a range of 160 to 210° C. for 30 to 120 min. Further, in terms of heat resistance, it is preferred that the glass-transition temperature (Tg) of the cured product be not lower than 150° C. This Tg is based on data measured via DMA (Dynamic Mechanical Analysis).

### Other Aspects

Moreover, the heat-curable resin composition of the present invention may be applied to various items such as semiconductor devices, coverlay films and electromagnetic shielding materials.

The present invention is described in detail hereunder with reference to working and comparative examples. However, the present invention is not limited to the following working examples.

### Working Example

### (A) Polyphenylene Ether Resin Having Reactive Double Bonds at Molecular Chain Ends

(A-1): Terminated styrene-modified polyphenylene ether resin represented by the following formula (OPE-2St-1200 by MITSUBISHI GAS CHEMICAL COMPANY, INC., number average molecular weight 1,200)

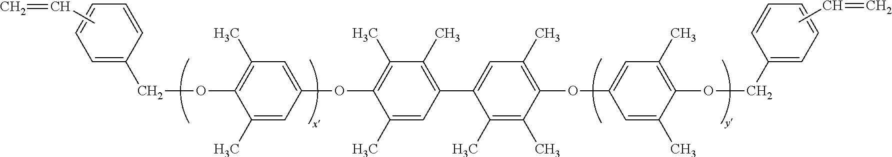

In the above formula, x′ represents 0 to 20, y′ represents 0 to 20, provided that x′ and y′ do not both represent 0 at the same time.

### (B) (Meth)Acrylic Acid Ester Compound

(B-1): Bifunctional acrylate (9,9-bis[4-(2-hydroxyethoxy)phenyl]fluorene diacrylate, A-BPEF by Shin-Nakamura Chemical Co., Ltd)

(B-2): Bifunctional acrylate (tricyclodecane dimethanol diacrylate, A-DCP by Shin-Nakamura Chemical Co., Ltd)

(B-3): Bifunctional acrylate (tricyclodecane dimethanol dimethacrylate, DCP by Shin-Nakamura Chemical Co., Ltd)

(C) Cyclic Imide Compound Containing, in One Molecule, at Least One Dimer Acid Backbone, at Least One Linear Alkylene Group Having not Less than 6 Carbon Atoms, and at Least Two Cyclic Imide Groups

(C-1): Linear alkylene group-containing maleimide compound represented by the following formula (BMI-3000 gel by Designer Molecules Inc.; content ratio of compound having a number average molecular weight of not larger than 1,000 is about 12% by mass.)

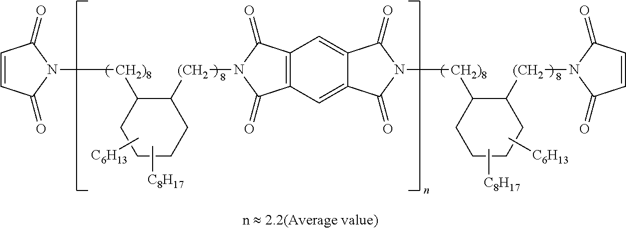

(C-2): Linear alkylene group-containing maleimide compound represented by the following formula (BMI-1500 by Designer Molecules Inc.; content ratio of compound having a number average molecular weight of not larger than 1,000 is about 20% by mass.)

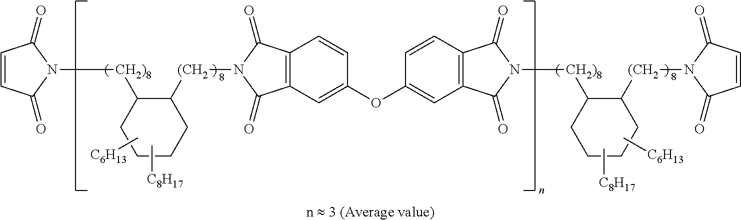

(C-3): 4,4′-diphenylmethanebismaleimide (BMI-1000 by Daiwa Fine Chemicals Co., Ltd.) (for comparative example)

(C-4): Linear alkylene group-containing maleimide compound represented by the following formula (BMI-3000) by Designer Molecules Inc.; content ratio of compound having a number average molecular weight of not larger than 1,000 is about 1% by mass.) (for comparative example)

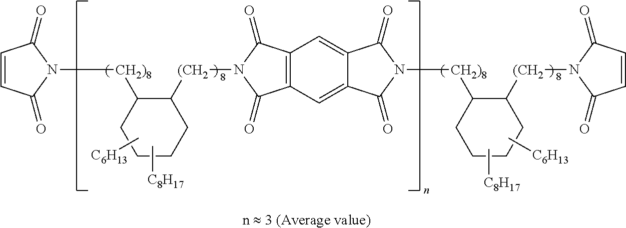

### (D) Reaction Initiator

(D-1): Dicumylperoxide (PERCUMYL D by NOF CORPORATION)

### (E) Inorganic Filler

(E-1): Silica prepared by treating molten spherical silica (SO-25R by Admatechs Company Limited, average particle size 0.5 μm) with methacrylic group-modified silane coupling agent (KBM-503 by Shin-Etsu Chemical Co., Ltd.)

### Working Examples 1 to 7; Comparative Examples 1 to 7

Components were dissolved and dispersed in anisole at the compounding ratios (parts by mass) shown in Tables 1 and 2, followed by making adjustments so that non-volatile constituents would be in an amount of 60% by mass, thus obtaining a varnish of a resin composition. A roller coater was then used to apply the varnish of the resin composition to a PET film having a thickness of 38 μm, in a way such that a thickness of the varnish applied would be 50 μm after drying. Drying was then performed at 80° C. for 15 min to obtain an uncured resin film. In the evaluation tests below, the PET film was peeled off from the uncured resin film that had been formed on the PET film, and such uncured resin film was actually used.

### Varnish Transparency

With regard to a varnish before film formation (composition containing components (A), (B), (C) and/or (D), but not containing component (E)), “∘” was given to examples where the anisole solution of the resin composition had no visible insoluble residues and turbidity, and exhibited, when contained in a quartz cell, a direct light transmittance of not lower than 50% at a light path of 1 mm and a wavelength of 740 nm, the direct light transmittance being measured by a spectrophotometer U-4100 (by Hitachi High-Tech Science Corporation); whereas “x” was given to examples exhibiting none of these features.

### Film Property

The uncured resin film was then bended by 90 degrees at 25° C. to visually confirm whether cracks or breakage had occurred therein. “∘” was given to examples exhibiting no cracks or breakage at all; whereas “x” was given to examples exhibiting even a small degree of cracks or breakage.

### Relative Permittivity, Dielectric Tangent

The uncured resin film was cured via stepwise curing where the uncured resin film was at first treated at 150° C. for an hour, and then at 180° C. for two hours, thereby obtaining a cured resin film. Later, a network analyzer (E5063-2D₅ by Keysight Technologies) and a stripline (by KEYCOM Corp.) were connected to the cured resin film so as to measure the relative permittivity and dielectric tangent thereof at a frequency of 10 GHz.

### Glass-Transition Temperature

The uncured resin film was cured via stepwise curing where the uncured resin film was at first treated at 150° C. for an hour, and then at 180° C. for two hours, thereby obtaining a cured resin film. After this cured resin film had cooled down thoroughly, DMA-800 manufactured by TA Instruments was used to measure the glass-transition temperature (Tg) of the cured resin film.

### Copper Foil Adhesion Force

At first, the uncured resin film was laminated on an E glass plate of a size of: length 80 mm×width 25 mm×thickness 1 mm at 80° C. Next, an electrolytic copper foil (MLS-G by MITSUI MINING & SMELTING CO., LTD) having a thickness of 12 μm was placed on a surface of the uncured resin film that was not laminated on the glass plate, followed by performing vacuum pressing under a pressure of 30 kg/cm² and at a temperature of 180° C. for 120 min, thereby obtaining a copper-clad laminate adhering to the glass plate via the cured resin film. With the glass plate part being fixed, the copper foil was then pulled in a similar manner as a 90° peeling test so as to measure an adhesion force between the copper foil and the resin.

TABLE 1

| | | | | Working example | | | | | | |
|---|---|---|---|---|---|---|---|---|---|---|
| Composition table (part by mass) | | | | 1 | 2 | 3 | 4 | 5 | 6 | 7 |
| (A) | Polyphenylene | OPE-2St-1200 | A-1 | 60.0 | 60.0 | 60.0 | 60.0 | 50.0 | 60.0 | 60.0 |
| | ether resin | | | | | | | | | |
| (B) | (Meth) acrylic | A-BPEF | B-1 | 10.0 | | | 10.0 | 10.0 | 10.0 | 10.0 |
| | acid ester | A-DCP | B-2 | | 10.0 | | | | | |
| | compound | DCP | B-3 | | | 10.0 | | | | |
| (C) | Cyclic imide | BMI-3000gel | C-1 | 30.0 | 30.0 | 30.0 | 25.0 | 40.0 | 30.0 | 30.0 |
| | compound | BMI-1500 | C-2 | | | | 5.0 | | | |
| | | BMI-1000 | C-3 | | | | | | | |
| | | BMI-3000J | C-4 | | | | | | | |
| (D) | Reaction initiator | PERCUMYL D | D-1 | 1.0 | 1.0 | 1.0 | 1.0 | 1.0 | 1.0 | 1.0 |
| (E) | Inorganic filler | Treated silica | E-1 | | | | | | 70.0 | 235.0 |

| | | | | | | | | | |
|---|---|---|---|---|---|---|---|---|---|
| Property | Varnish transparency | | ∘ | ∘ | ∘ | ∘ | ∘ | ∘ | ∘ |
| evaluation | Film property | | ∘ | ∘ | ∘ | ∘ | ∘ | ∘ | ∘ |
| | Relative permittivity (10 GHz) | | 2.7 | 2.5 | 2.5 | 2.5 | 2.4 | 2.7 | 3.0 |
| | Dielectric tangent (10 GHz) | | 0.004 | 0.003 | 0.003 | 0.003 | 0.002 | 0.002 | 0.001 |
| | Glass-transition temperature (DMA) | ° C. | 184 | 182 | 185 | 176 | 170 | 184 | 184 |
| | Copper foil adhesion force | kN/m | 0.9 | 0.9 | 1.1 | 1.3 | 1.1 | 0.9 | 0.8 |

TABLE 2

| | | | | Comparative example | | | | | | |
|---|---|---|---|---|---|---|---|---|---|---|
| Composition table (part by mass) | | | | 1 | 2 | 3 | 4 | 5 | 6 | 7 |
| (A) | Polyphenylene | OPE-2St-1200 | A-1 | 60.0 | 60.0 | 60.0 | | 60.0 | 60.0 | 100.0 |
| | ether resin | | | | | | | | | |
| (B) | (Meth) acrylic | A-BPEF | B-1 | 10.0 | 10.0 | 10.0 | 10.0 | | | |
| | acid ester | A-DCP | B-2 | | | | | | | |
| | compound | DCP | B-3 | | | | | | | |
| (C) | Cyclic imide | BMI-3000gel | C-1 | | | | | | 40.0 | |
| | compound | BMI-1500 | C-2 | | | | | | | |
| | | BMI-1000 | C-3 | 30.0 | | | | | | |
| | | BMI-3000J | C-4 | 30.0 | 30.0 | 30.0 | 90.0 | 40.0 | | |
| (D) | Reaction initiator | PERCUMYL D | D-1 | 1.0 | 1.0 | 1.0 | 1.0 | 1.0 | 1.0 | 1.0 |
| (E) | Inorganic filler | Treated silica | E-1 | | | 100.0 | | | | |

| | | | | | | | | | |
|---|---|---|---|---|---|---|---|---|---|
| Property | Varnish transparency | | x | x | x | ∘ | x | ∘ | ∘ |
| evaluation | Film property | | x | ∘ | x | ∘ | ∘ | ∘ | x |
| | Relative permittivity (10 GHz) | | * 1 | 2.7 | * 2 | 2.4 | 2.5 | 2.5 | * 1 |
| | Dielectric tangent (10 GHz) | | | 0.004 | | 0.002 | 0.002 | 0.002 | |
| | Glass-transition temperature (DMA) | ° C. | | * 2 | | 75 | * 2 | 178 | |
| | Copper foil adhesion force | kN/m | | 0.6 | | 1.3 | 0.4 | 0.4 | |

* 1: Cured resin film failed to be produced, or property evaluation of cured resin film was difficult even when cured resin film was able to be produced.
* 2: Due to curing unevenness, measurement values of dielectric property were different depending on parts measured and/or measurement values of glass-transition temperature were not readable clearly.

According to the above results, the heat-curable resin composition of the present invention exhibited superior compatibilities among the components, a low degree of curing unevenness at the time of curing, and a low level of variation in properties. Further, the cured product(s) of this composition had a high glass-transition temperature, a low dielectric tangent, and a superior adhesion to a metal foil. Thus, the heat-curable resin composition of the present invention is suitable for use in an adhesive agent, a film, a prepreg, a laminate, a circuit board and a printed-wiring board.

What is claimed is:

1. A heat-curable resin composition comprising:
(A) a polyphenylene ether resin having reactive double bonds at molecular chain ends;
(B) a (meth)acrylic acid ester compound;
(C) a cyclic imide compound containing, in one molecule, at least one dimer acid backbone, at least one linear alkylene group having not less than 6 carbon atoms, and at least two cyclic imide groups; and
(D) a reaction initiator.

2. The heat-curable resin composition according to claim 1, wherein the polyphenylene ether resin as the component (A) is represented by the following formula (1): 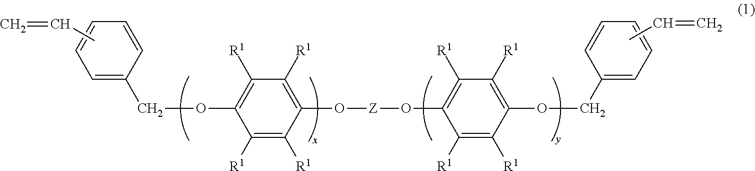
wherein R¹ independently represents a hydrogen atom or an aliphatic hydrocarbon group having 1 to 6 carbon atoms; Z represents a divalent aromatic hydrocarbon group having 6 to 24 carbon atoms; x represents a number of 0 to 20, y represents a number of 0 to 20, provided that x and y do not both represent 0 at the same time.

3. The heat-curable resin composition according to claim 2, wherein the divalent aromatic hydrocarbon group having 6 to 24 carbon atoms, as represented by Z in the formula (1), is selected from divalent aromatic hydrocarbon groups expressed by the following formula (2): 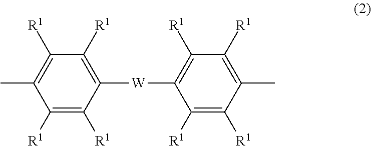
wherein R¹ independently represents a hydrogen atom or an aliphatic hydrocarbon group having 1 to 6 carbon atoms; W represents a single bond, or a linear, branched or cyclic divalent aliphatic hydrocarbon group having 1 to 10 carbon atoms.

4. The heat-curable resin composition according to claim 1, wherein the polyphenylene ether resin as the component (A) is represented by the following formula (3): 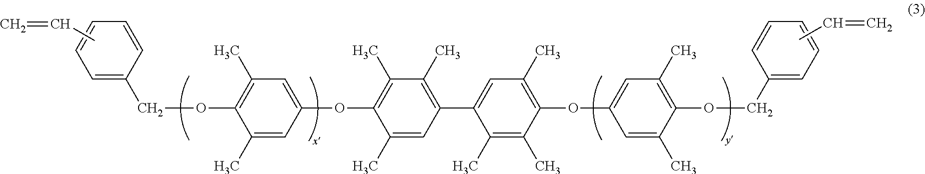
wherein x′ represents 0 to 20, y′ represents 0 to 20, provided that x′ and y′ do not both represent 0 at the same time.

5. The heat-curable resin composition according to claim 1, wherein the (meth)acrylic acid ester compound as the component (B) has not less than 8 carbon atoms, and at least 2 (meth)acrylic groups in one molecule.

6. The heat-curable resin composition according to claim 1, wherein the cyclic imide compound as the component (C) is represented by the following formula (4): 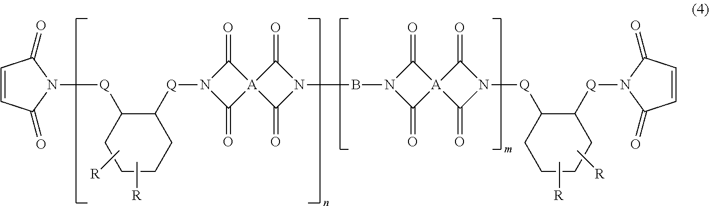
wherein A independently represents a tetravalent organic group having an aromatic or aliphatic ring; B represents an alkylene group having 6 to 18 carbon atoms and a divalent aliphatic ring that may contain a hetero atom; Q independently represents a linear alkylene group having not less than 6 carbon atoms; R independently represents a linear or branched alkyl group having not less than 6 carbon atoms; n represents a number of 1 to 10; m represents a number of 0 to 10.

7. The heat-curable resin composition according to claim 6, wherein A in the formula (4) represents any of the following structures: 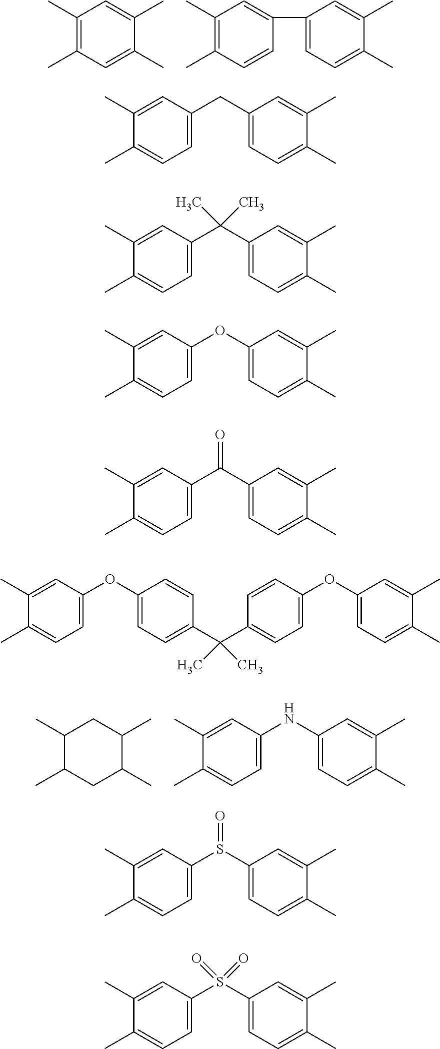
wherein bonds in the above structural formulae that are yet unbonded to substituent groups are to be bonded to carbonyl carbons forming cyclic imide structures in the general formula (4).

8. The heat-curable resin composition according to claim 1, wherein not lower than 5% by mass of the cyclic imide compound as the component (C) has a number average molecular weight of 1,000 or smaller.

9. The heat-curable resin composition according to claim 1, further comprising an inorganic filler as a component (E).

10. The heat-curable resin composition according to claim 9, wherein the inorganic filler as the component (E) has been treated with a silane coupling agent having organic groups capable of reacting with the component (C).

11. An adhesive agent comprising the heat-curable resin composition according to claim 1.

12. A film comprising the heat-curable resin composition according to claim 1.

13. A cured product of the heat-curable resin composition according to claim 1.

14. A prepreg having the cured product according to claim 13.

15. A laminate having the cured product according to claim 13.

16. A circuit board having the cured product according to claim 13.

17. A printed-wiring board having the cured product according to claim 13.
